(19) United States
(12) Patent Application Publication
(10) Pub. No.: US 2026/0247916 A1
(43) Pub. Date: Aug. 20, 2026

(54) ELECTROSTATIC CHUCK FILM

(71) Applicant: YOULCHON CHEMICAL CO., LTD., Seoul (KR)

(72) Inventors: Ji Moon LEE, Ansan-si (KR); Sang Gil DOH, Ansan-si (KR); Gyeong Seok YU, Ansan-si (KR); Kyu Wan LEE, Ansan-si (KR); Chang Woo LEE, Ansan-si (KR); Young Hun JANG, Ansan-si (KR); Han Bin CHO, Ansan-si (KR)

(73) Assignee: YOULCHON CHEMICAL CO., LTD., Seoul (KR)

(21) Appl. No.: 19/161,898

(22) PCT Filed: Nov. 27, 2024
(86) PCT No.: PCT/KR2024/018959

§ 371 Date: Sep. 3, 2025

(30) Foreign Application Priority Data
Dec. 11, 2023 (KR) 10-2023-0178854
Jul. 31, 2024 (KR) 10-2024-0101920

(51) Int. Cl. H10P 72/72; B32B 7/06; B32B 7/12

(52) U.S. Cl. CPC H10P 72/72; B32B 7/06; B32B 7/12; B32B 2307/202; B32B 2307/7376

(57) ABSTRACT

The present disclosure relates to an electrostatic chuck film, and more particularly, to an electrostatic chuck film including an adhesive layer formed on a conductive layer and having electrical properties in a predetermined range and a thickness of each layer.

### TECHNICAL FIELD

The present disclosure relates to an electrostatic chuck film, and more particularly, to an electrostatic chuck film including an adhesive layer formed on a conductive layer, having electrical properties in a predetermined range and a thickness of each layer, and having one side capable of being picked up by an electrostatic chuck and an opposite side capable of adhering.

### BACKGROUND ART

Generally, an adhesive protective film is attached to protect the surface of a product during a product manufacturing process. Such adhesive protective films are used particularly in display panels such as liquid crystal panels, plasma display panels (PDPs), etc. that constitute display devices such as mobile phones, computer monitors, TVs, and various billboards, semiconductor packaging processes, and the like.

In the related art, a process of picking-up films or products using a pressure was in the main, but it is impossible to use the pressure to pick up films or products in a vacuum.

Specifically, a semiconductor packaging process is performed in a vacuum state, and in the vacuum state, a conventional adhesive force was used to pick up films or products, but there is a disadvantage of being not easy to be attached or detached, so that specialized structures and characteristics such as an electrostatic chuck are required.

Korean Patent Registration No. 2208071 discloses a multilayer structure for electrostatic coupling of a substrate, but there is a disadvantage of requiring an external power source and a contact part thereof for charging of a metal electrode.

Furthermore, in the case of products, a separate component is required to enable pick-up by the electrostatic chuck, but such a component may be unnecessary for the product or may deteriorate the function of the product itself. Therefore, there is a great demand in the industry for a pick-up body having a new structure and characteristics capable of solving these problems.

### PRIOR ARTS

### Patent Documents

Patent Document 1: KR 10-2208071 (FRAUNHOFER-GESELLSCHAFT ZUR FÖRDERUNG DER ANGEWANDTEN FORSCHUNG E.V.) Jan. 21, 2021

### DISCLOSURE

### Technical Problem

The present disclosure has been made to solve the above problems, and an object of the present disclosure is to provide an electrostatic chuck film including an adhesive layer formed on a conductive layer and having electrical properties in a predetermined range, one side capable of being picked up by an electrostatic chuck and an opposite side capable of adhering.

The present disclosure may also achieve other objects that may be easily derived by those skilled in the art from such an object and the overall technology of the present specification, in addition to the clear object.

### Technical Solution

In order to achieve the above-described object, the present disclosure provides an electrostatic chuck film including:
a base layer,
a conductive layer formed on the base layer, and
an adhesive layer formed on the conductive layer.

In addition, the base layer may be selected from the group consisting of polyethylene terephthalate, polyethylene, polyimide, acrylic resin, cycloolefin polymer, mixtures thereof, and copolymers thereof.

In addition, the electrostatic chuck film of the present disclosure may further include a release film formed on the adhesive layer.

In addition, when a voltage of 1 kV is applied to the electrostatic chuck film, the surface resistance may be 1×10¹¹ to 1×10¹³ Ω/sq.

In addition, when the voltage of 1 kV is applied to a laminate of the base layer and the conductive layer, the surface resistance may be 1×10³ to 1×10⁷ Ω/sq.

In addition, when the voltage of 1 kV is applied to the adhesive layer, the surface resistance may be greater than 1×10¹³ Ω/sq.

In addition, the dielectric loss of the electrostatic chuck film under a 25° C. 10 GHz condition may be 0.02 to 0.1.

In addition, the dielectric loss of the laminate of the base layer and the conductive layer under a 25° C. 10 GHz condition may be 0.1 to 0.23.

In addition, the dielectric loss of the laminate of the base layer and the adhesive layer under a 25° C. 10 GHz condition may be 0.007 to 0.009.

In addition, the dielectric constant of the electrostatic chuck film under a 25° C. 10 GHz condition may be 2.8 to 3.3.

In addition, the dielectric constant of the laminate of the base layer and the conductive layer under a 25° C. 10 GHz condition may be 3.0 to 3.5.

In addition, the dielectric constant of the laminate of the base layer and the adhesive layer under a 25° C. 10 GHz condition may be 2.9 to 3.2.

In addition, the conductive layer may be selected from the group consisting of poly(3,4-ethylenedioxythiophene (PEDOT), poly(3,4-ethylenedioxythiophene) polystyrenesulfonate (PEDOT-PSS), carbon nanotubes (CNT), graphene, indium tin oxide (ITO), silver nanowires, and combinations thereof.

In addition, a crosslinking reaction may occur in the conductive layer.

In addition, the conductive layer may be formed by crosslinking a mixture of poly(3,4-ethylenedioxythiophene) polystyrenesulfonate and water-dispersed polyurethane with an aziridine compound.

In addition, the aziridine compound may be selected from the group consisting of trimethylolpropane tris(2-methyl-1-aziridine)propionate, trimethylolpropane tris[3-(aziridin-1-yl)propionate], pentaerythritol tris[3-(1-aziridinyl)propionate], pentaerythritol tris(2-methyl-1-aziridine propionate) and mixtures thereof.

In addition, the weight ratio of polyurethane to poly(3,4-ethylenedioxythiophene) polystyrenesulfonate of the conductive layer may be 1:9, 1.5:8.5 or 3:7.

In addition, the weight ratio of the mixture of poly(3,4-ethylenedioxythiophene) polystyrenesulfonate and water-dispersed polyurethane of the conductive layer to the aziridine compound may be 100:8 to 63, 100:10 to 63, or 100:12 to 63.

In addition, the mixture of poly(3,4-ethylenedioxythiophene) polystyrenesulfonate and water-dispersed polyurethane of the conductive layer may be a solution dissolved in a solvent selected from the group consisting of water, ethanol, methanol, isopropyl alcohol, and a mixture thereof.

In addition, the solution may further include a stabilizer selected from the group consisting of ethylene glycol, sorbitol and a mixture thereof.

In addition, the concentration of the mixture of poly(3,4-ethylenedioxythiophene) polystyrenesulfonate and polyurethane dissolved in the solvent selected from the group consisting of water, ethanol, methanol, isopropyl alcohol, and mixtures thereof may be 0.8 to 1.2 wt % or 0.8 to 0.9 wt %.

In addition, the thickness of the conductive layer may be 0.03 to 3 μm.

In addition, the adhesive layer may be selected from the group consisting of silicone, acrylic resin, urethane resin, rubber, and combinations thereof.

In addition, a curing reaction may occur in the adhesive layer.

In addition, the adhesive layer may be formed by reacting a silane or silane derivative with a compound selected from the group consisting of organopolysiloxane, chlorosilane, alkylalkoxysilane, sulfursilane, aminosilane, epoxysilane, and mixtures thereof, which contain vinyl groups at both ends.

In addition, platinum may be used as a catalyst in the reaction of the silane or the silane derivative with the compound selected from the group consisting of organopolysiloxane, chlorosilane, alkylalkoxysilane, sulfursilane, aminosilane, epoxysilane, and mixtures thereof.

In addition, the organopolysiloxane may be polydimethylsiloxane containing vinyl groups at both ends, and the vinyl group content may be 0.02 to 0.2 mmol/g, 0.1 to 0.2 mmol/g, or 0.15 to 0.2 mmol/g.

In addition, in the silane derivative, 1 to 2 hydroxyl groups (—H) may be substituted with alkyl groups having 1 to 2 carbon atoms.

In addition, the Si—H content of the silane or silane derivative may be 4 to 16 mmol/g, 4 to 10 mmol/g, or 4 to 5 mmol/g.

In addition, the Si—H molar ratio of the silane or silane derivative may be 1 to 3 with respect to the vinyl groups contained in both ends of the compound selected from the group consisting of organopolysiloxane, chlorosilane, alkylalkoxysilane, sulfursilane, aminosilane, epoxysilane, and mixtures thereof.

In addition, the thickness of the adhesive layer may be 15 to 50 μm, 18 to 35 μm, or 20 to 25 μm.

In addition, the thickness of the base layer may be 25 to 100 μm, 33 to 70 μm, or 38 to 50 μm.

In addition, the conductive layer may be gravure-coated on the base layer.

In addition, the conductive layer may be dried with hot air at 60 to 100° C. or 20 to 35 Hz for 30 to 90 seconds.

In addition, the adhesive layer may be slot-die-coated or comma-coated on the conductive layer.

In addition, the adhesive layer may be dried with hot air at 60 to 150° C. or 30 to 35 Hz for 90 to 180 seconds.

### Advantageous Effects

According to the technical solution of the present disclosure as described above, various effects including the following can be expected. However, the present disclosure is not established only when all of the following effects are exhibited.

According to the present disclosure, the electrostatic chuck film can be picked up by an electrostatic chuck in a vacuum state by preparing the film in the order of a base layer-conductive layer-adhesive layer, and appropriately controlling electrical properties such as surface resistance, dielectric loss, and dielectric constant and the thickness of each layer.

In particular, when the electrostatic chuck film of the present disclosure is attached to the electrostatic chuck, an opposite side can adhere to a product such as a semiconductor wafer and the like. Accordingly, wafers and the like attached with the electrostatic chuck film of the present disclosure can be easily attached or detached to or from the electrostatic chuck as needed in a vacuum state, and there is an advantage of preventing deterioration of the functions of the product by removing the electrostatic chuck film of the present disclosure outside of the vacuum state.

### DESCRIPTION OF DRAWINGS

FIG. 1 is a cross-sectional view illustrating an example of the present disclosure.

FIG. 2 is a cross-sectional view illustrating another example of the present disclosure.

### MODES

Hereinafter, preferred examples of the present disclosure will be described in detail.

However, the following are only specific examples exemplified and described in detail, and since the present disclosure may be variously modified and may have various forms, the present disclosure is not limited to the specific examples exemplified. It should be understood that the present disclosure includes all modifications, equivalents, or substitutes included in the spirit and technical scope of the present disclosure.

In addition, many specific details such as specific components will be described in the following description, which are provided only to help a more overall understanding of the present disclosure, and it will be obvious to those skilled in the art that the present disclosure may be implemented without these specific details. Further, in describing the present disclosure, when a detailed description of known related functions or configurations is determined to unnecessarily obscure the gist of the present disclosure, the detailed description will be omitted.

In addition, terms used in the present disclosure are used only to describe specific examples, and are not intended to limit the present disclosure. Unless otherwise defined, all terms used herein including technological or scientific terms have the same meanings as those generally understood by those skilled in the art to which the present disclosure pertains. Terms which are defined in a generally used dictionary should be interpreted to have the same meaning as the meaning in the context of the related art, and are not interpreted as ideal or excessively formal meanings unless otherwise clearly defined in the present disclosure.

In the present disclosure, a singular expression includes a plural expression unless otherwise clearly defined in a context.

In the present disclosure, unless specified separately, % refers to wt %, and unless specified separately, a molecular weight refers to a weight average molecular weight.

In the present disclosure, the terms including as first, second, and the like may be used for describing various components, but the components are not limited by the terms. These terms are only used to distinguish one component from another component. For example, without departing from the scope of the present disclosure, a first component may be named as a second component, and similarly, a second component may be named as a first component.

In the present disclosure, terms such as “including”, “containing”, or “having” are intended to indicate the presence of features, components (or constituents) described in the specification, but do not mean that one or more other features or components are not present or may not be added.

When an adhesive film capable of being picked up by an electrostatic chuck is attached to a product such as a semiconductor wafer, etc., the adhesive film may be easily attached and detached even in a vacuum state, and the film may be removed outside of the vacuum state to prevent deterioration of the functions of wafers, etc. An object of the present disclosure is to provide an electrostatic chuck film capable of exhibiting these advantages.

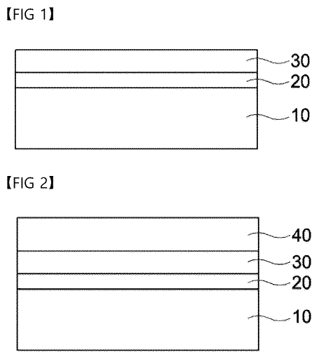

In order to achieve the above-described object, the electrostatic chuck film of the present disclosure includes, as illustrated in FIG. 1,
a base layer 10,
a conductive layer 20 formed on the base layer 10, and
an adhesive layer 30 formed on the conductive layer 20. The present disclosure has a main feature in that the constituent layers are arranged in the order.

In addition, the base layer 10 may be selected from the group consisting of polyethylene terephthalate, polyethylene, polyimide, acrylic resin, cycloolefin polymer, mixtures thereof, and copolymers thereof.

In addition, the electrostatic chuck film of the present disclosure may further include a release film 40 formed on the adhesive layer 30 as illustrated in FIG. 2.

In addition, when a voltage of 1 kV is applied to the electrostatic chuck film, the surface resistance may be 1×10¹¹ to 1×10¹³ Ω/sq. When the surface resistance is less than the above range, the dielectric loss increases and thus it may not function as an electrostatic chuck, and on the contrary, when the surface resistance exceeds the above range, the dielectric loss decreases, but the mobility of electrons decreases, and thus it may not function as the electrostatic chuck.

In addition, when the voltage of 1 kV is applied to a laminate of the base layer 10 and the conductive layer 20, the surface resistance may be 1×10³ to 1×10⁷ Ω/sq. When the surface resistance is less than the above range, the dielectric loss increases and thus it may not function as an electrostatic chuck, and on the contrary, when the surface resistance exceeds the above range, the dielectric loss decreases, but the mobility of electrons decreases, and thus it may not function as the electrostatic chuck.

In addition, when the voltage of 1 kV is applied to the adhesive layer 30, the surface resistance may be greater than 1×10¹³ Ω/sq, and when the surface resistance is 1×10¹³ Ω/sq or less, the dielectric loss increases and thus it may not function as an electrostatic chuck.

In addition, the dielectric loss of the electrostatic chuck film under a 25° C. 10 GHz condition may be 0.02 to 0.1. When the dielectric loss is less than the above range, the mobility of electrons decreases, and thus an environment in which positive charges and an electrostatic force may be generated in the electrostatic chuck is not created, so that it may not function as an electrostatic chuck. On the contrary, when the dielectric loss exceeds the above range, the mobility of electrons increases, and the loss of negative charges increases before an electrostatic force with the electrostatic chuck is generated, so that it may not function as the electrostatic chuck.

In addition, the dielectric loss of the laminate of the base layer and the conductive layer under a 25° C. 10 GHz condition may be 0.1 to 0.23. When the dielectric loss is less than the above range, the dielectric loss is small, and thus a problem may occur in which the electrostatic chuck is not separated due to positive or negative charges of the electrostatic chuck that may remain when the applied voltage of the electrostatic chuck is turned off. On the contrary, when the dielectric loss exceeds the above range, the number of electrons that may be bound with the electrostatic chuck is small, so that the electrostatic repulsion force may be reduced or eliminated.

In addition, the dielectric loss of the laminate of the base layer and the adhesive layer under a 25° C. 10 GHz condition may be 0.007 to 0.009. When the dielectric loss is less than the above range, the dielectric loss is small, and thus a problem may occur in which the electrostatic chuck is not separated due to the positive or negative charges of the electrostatic chuck that may remain when the applied voltage of the electrostatic chuck is turned off. On the contrary, when the dielectric loss exceeds the above range, the number of electrons that may be bound with the electrostatic chuck is small, so that the electrostatic repulsion force may be reduced or eliminated.

In addition, the dielectric constant of the electrostatic chuck film under a 25° C. 10 GHz condition may be 2.8 to 3.3. When the dielectric constant is less than the above range, the dielectric constant is low, and thus an electrostatic force with the electrostatic chuck is not generated, and on the contrary, when the dielectric constant exceeds the above range, the dielectric constant is high, and thus the mobility of electrons may not be secured, so that the electrostatic force with the electrostatic chuck may not be generated.

In addition, the dielectric constant of the laminate of the base layer and the conductive layer under a 25° C. 10 GHz condition may be 3.0 to 3.5. When the dielectric constant is less than the above range, the amount of charges to be stored is small, so that the electrostatic repulsion force may be reduced or eliminated, and on the contrary, when the dielectric constant exceeds the above range, the amount of charges to be stored is large, so that even while the applied voltage is turned off, there may be a problem of not being separated from the electrostatic chuck or being attracted to the electrostatic chuck.

In addition, the dielectric constant of the laminate of the base layer and the adhesive layer under a 25° C. 10 GHz condition may be 2.9 to 3.2. When the dielectric constant is less than the above range, the amount of charges to be stored is small, so that the electrostatic repulsion force may be reduced or eliminated, and on the contrary, when the dielectric constant exceeds the above range, the amount of charges to be stored is large, so that even while the applied voltage is turned off, there may be a problem of not being separated from the electrostatic chuck or being attracted to the electrostatic chuck.

The main feature of the present disclosure is to enable pick-up by the electrostatic chuck by precisely controlling the electrical properties such as surface resistance, dielectric loss, or dielectric constant of each layer and the electrostatic chuck film combining the layers.

In addition, the conductive layer 20 may be selected from the group consisting of poly(3,4-ethylenedioxythiophene (PEDOT), poly(3,4-ethylenedioxythiophene) polystyrenesulfonate (PEDOT-PSS), carbon nanotubes (CNT), graphene, indium tin oxide (ITO), silver nanowires, and combinations thereof. The conductive layer 20 constituting the present disclosure is characterized to essentially require transparency in addition to the electrical properties.

In addition, when the adhesive layer 30 is formed on the conductive layer 20 in the electrostatic chuck film of the present disclosure, the conductive layer 20 may partially be removed by a solvent that dissolves materials constituting the adhesive layer 30. The problem occurs when slot-die coating or comma coating is performed to form the adhesive layer 30 with a predetermined thickness, and in order to prevent this problem, it is necessary to improve the solvent resistance of the conductive layer 20.

In order to improve the solvent resistance, a reaction between functional groups in the constituent materials of the conductive layer 20 may be induced, or a crosslinking reaction may be induced by introducing a separate crosslinking agent.

For example, when the conductive layer 20 of the present disclosure is a mixture of poly(3,4-ethylenedioxythiophene) polystyrenesulfonate and water-dispersed polyurethane, an aziridine compound may be introduced as a crosslinking agent to cause a crosslinking reaction.

In addition, the aziridine compound may be selected from the group consisting of trimethylolpropane tris(2-methyl-1-aziridine)propionate, trimethylolpropane tris[3-(aziridin-1-yl)propionate], pentaerythritol tris[3-(1-aziridinyl)propionate], pentaerythritol tris(2-methyl-1-aziridine propionate) and mixtures thereof.

In addition, a weight ratio of polyurethane to poly(3,4-ethylenedioxythiophene) polystyrenesulfonate (PEDOT-PSS) in the conductive layer 20 may be 1:9, 1.5:8.5, or 3:7. When the PEDOT-PSS content is less than the above range, the surface resistance, dielectric loss, and dielectric constant conditions that may function as the electrostatic chuck may not be satisfied. On the contrary, when the PEDOT-PSS content exceeds the above range, physical properties may be satisfied, but the amount of polyurethane is small and thus may not be sufficiently crosslinked with the aziridine crosslinking agent, so that the solvent resistance is not ensured, and it is also not preferable in an economic aspect.

In addition, the weight ratio of the mixture of poly(3,4-ethylenedioxythiophene) polystyrenesulfonate and water-dispersed polyurethane of the conductive layer 20 to the aziridine compound may be 100:8 to 63, 100:10 to 63, or 100:12 to 63. When the weight ratio of the aziridine compound is less than the above range, the aziridine compound is not sufficiently crosslinked with carboxyl groups of the water-dispersed polyurethane, so that the solvent resistance is not ensured. On the contrary, when the weight ratio of the aziridine compound exceeds the above range, an unreacted aziridine compound may migrate to the surface according to time and temperature, which is economically undesirable.

In addition, the mixture of poly(3,4-ethylenedioxythiophene) polystyrenesulfonate and water-dispersed polyurethane of the conductive layer 20 may be a solution dissolved in a solvent selected from the group consisting of water, ethanol, methanol, isopropyl alcohol, and a mixture thereof.

In addition, the solution may further include a stabilizer selected from the group consisting of ethylene glycol, sorbitol and a mixture thereof.

In addition, the concentration of the mixture of poly(3,4-ethylenedioxythiophene) polystyrenesulfonate and polyurethane dissolved in the solvent selected from the group consisting of water, ethanol, methanol, isopropyl alcohol, and mixtures thereof may be 0.8 to 1.2 wt % or 0.8 to 0.9 wt %. When the concentration of the solution is less than the above range, particles of PEDOT-PSS may come out to the surface to generate a coating strip on the coating surface. On the contrary, when the concentration of the solution exceeds the above range, the solid content is lowered, and when a Wet thickness is increased, the surface may not be even due to the fluidity of a coating solution on the coating surface.

In addition, the thickness of the conductive layer 20 may be 0.03 to 3 μm. When the thickness of the conductive layer is less than the above range, the surface resistance is high and the dielectric loss is lowered, so that it may not function as an electrostatic chuck. On the contrary, when the thickness of the conductive layer exceeds the above range, the surface resistance is lowered and the dielectric loss is increased, so that it may not function as an electrostatic chuck.

In addition, the adhesive layer 30 may be selected from the group consisting of silicone, acrylic resin, urethane resin, rubber, and combinations thereof.

In addition, the adhesive layer 30 may be formed by reacting a silane or silane derivative with a compound selected from the group consisting of organopolysiloxane, chlorosilane, alkylalkoxysilane, sulfursilane, aminosilane, epoxysilane, and mixtures thereof, which contain vinyl groups at both ends. At this time, it is preferred to use platinum as a catalyst. In the present disclosure, an addition reaction (curing) step may be particularly applied in order to increase the degree of curing and decrease the dielectric constant.

In addition, the organopolysiloxane is polydimethylsiloxane containing vinyl groups at both ends, and the molecular weight thereof is 600,000 to 700,000 in weight average molecular weight and 300,000 to 400,000 in number average molecular weight, and the vinyl group content may be 0.02 to 0.2 mmol/g, 0.1 to 0.2 mmol/g, or 0.15 to 0.2 mmol/g. When the vinyl group content is less than the above range, the vinyl groups are not sufficiently crosslinked with Si—H and thus it may not function as the electrostatic chuck as a dielectric loss value increases. On the contrary, when the vinyl group content exceeds the above range, the crosslinking density with Si—H is increased and thus it may not function as the electrostatic chuck as the dielectric loss value decreases.

In addition, in the silane derivative, 1 to 2 hydroxyl groups (—H) may be substituted with alkyl groups having 1 to 2 carbon atoms.

In addition, the Si—H content of the silane or silane derivative may be 4 to 16 mmol/g, 4 to 10 mmol/g, or 4 to 5 mmol/g. When the Si—H content is less than the above range, the Si—H may not be sufficiently crosslinked with the vinyl groups, and thus the dielectric loss may be increased. On the contrary, when the Si—H content exceeds the above range, unreacted Si—H groups may be generated to migrate to the surface of the adhesive layer.

Preferably, in the silane or silane derivative, 1 to 2 hydroxyl groups (—H) of the hydrogen siloxane copolymer may be substituted with alkyl groups having 1 to 2 carbon atoms. More preferably, the silane or silane derivative may be an alkylhydrosiloxane-dialkylsiloxane copolymer, and more preferably, a methylhydrosiloxane-dimethylsiloxane copolymer.

In addition, the Si—H molar ratio (Si—H/vinyl) of the silane or silane derivative may be 1 to 3 with respect to the vinyl groups contained in both ends of the compound selected from the group consisting of organopolysiloxane, chlorosilane, alkylalkoxysilane, sulfursilane, aminosilane, epoxysilane, and mixtures thereof. When the Si—H/vinyl molar ratio exceeds the above range, the crosslinking density increases, but an out-gassing phenomenon occurs due to hydrogen gas generated when the amount of Si—H that has not reacted with vinyl increases. On the contrary, when the Si—H/vinyl molar ratio is less than the above range, a crosslinking point with vinyl decreases, and thus the crosslinking density and the dielectric constant are decreased, and the dielectric loss is increased, so that it may not function as the electrostatic chuck.

In addition, the thickness of the adhesive layer 30 may be 15 to 50 μm, 18 to 35 μm, or 20 to 25 μm. When the thickness of the adhesive layer 30 is less than the above range, the dielectric loss is increased and thus it may not function as the electrostatic chuck, and on the contrary, when the thickness of the adhesive layer 30 exceeds the above range, the dielectric loss is decreased, and thus it may not function as the electrostatic chuck.

In addition, the thickness of the base layer 10 may be 25 to 100 μm, 33 to 70 μm, or 38 to 50 μm. When the thickness of the base layer 10 is less than the above range, wrinkles may be generated due to shrinkage in a thermal process during coating, resulting in poor appearance. On the contrary, when the thickness of the base layer 10 exceeds the above range, the dielectric loss is lowered, so that it may not function as the electrostatic chuck.

The main feature of the present disclosure is to function as an electrostatic chuck by precisely controlling the thickness of each layer constituting the present disclosure.

In addition, the conductive layer 20 may be gravure-coated on the base layer 10.

In addition, the conductive layer 20 may be dried with hot air at 60 to 100° C. or 20 to 35 Hz for 30 to 90 seconds. When the drying time or the drying temperature is less than the above range, drying is insufficient, and thus curing or volatilization of the solvent is not completely performed, so that electric properties such as dielectric constant may be affected.

In addition, the adhesive layer 30 may be slot-die-coated or comma-coated on the conductive layer 20.

In addition, the adhesive layer 20 may be dried with hot air at 60 to 150° C. or 30 to 35 Hz for 90 to 180 seconds. When the drying time or the drying temperature is less than the above range, drying is insufficient, and thus curing or volatilization of the solvent is not completely performed, so that electric properties such as dielectric constant, etc. may be affected.

Hereinafter, Examples of the present disclosure will be described.

### EXAMPLE

### Preparation Example: Conductive Layer

A reaction product was obtained by crosslinking 0.8 wt % of an aqueous solution of a mixture of poly(3,4-ethylenedioxythiophene) polystyrenesulfonate (PEDOT-PSS) and water-dispersed polyurethane (PEDOT-PSS:polyurethane=1:9 wt) with different concentrations (0 wt %, 0.05 wt %, 0.09 wt %, 0.1 wt %, 0.3 wt %, 0.5 wt %, and 0.6 wt %) of pentaerythritol tris[3-(1-aziridinyl)propionate] at normal temperature and normal pressure for 45 minutes. Then, the reaction product was gravure-coated on a 50 μm-thick polyethylene terephthalate base layer, and dried with 35 Hz hot air at 60° C. for 20 sec, 80° C. for 20 sec, and 100° C. for 20 sec to form a 0.03 μm-thick conductive layer.

### Test Example 1: Solvent Resistance of Conductive Layer

When the applied voltage was 1 kV, the surface resistance of the conductive layer of Preparation Example above was measured with a surface resistance meter (Wolfgang, Germany), and a microfiber cloth soaked with methyl ethyl ketone (MEK) or ethanol was wrapped around an 800 g steel rod and brought into contact with the surface of the conductive layer, and added with a 300 g weight on the steel rod and rubbed 15 cm in one direction, repeating 3, 5, 7, 10, 15, and 20 times, respectively. Thereafter, when the applied voltage was 1 kV, the surface resistance of the conductive layer was measured with a surface resistance meter (Wolfgang, Germany). The results were shown in Table 1.

TABLE 1

| Surface resistance | | | | | | | | |
|---|---|---|---|---|---|---|---|---|
| (Ω/sq) | | | | | | | | |
| | Number | Aziridine concentration (wt %) | | | | | | |
| Solvent | of times | 0 | 0.05 | 0.09 | 0.1 | 0.3 | 0.5 | 0.6 |
| — | — | 3.44 × 10⁵ | 2.31 × 10⁵ | 3.11 × 10⁵ | 4.16 × 10⁵ | 3.41 × 10⁵ | 3.12 × 10⁵ | NG |
| MEK | 3 | 6.82 × 10⁷ | 5.33 × 10⁵ | 4.18 × 10⁵ | 6.12 × 10⁵ | 5.41 × 10⁵ | 4.16 × 10⁵ | |
| Ethanol | 3 | 8.43 × 10⁶ | 5.72 × 10⁵ | 3.84 × 10⁵ | 6.55 × 10⁵ | 5.62 × 10⁵ | 3.54 × 10⁵ | |
| | 5 | 5.23 × 10⁷ | 8.81 × 10⁵ | 4.21 × 10⁵ | 5.26 × 10⁵ | 4.98 × 10⁵ | 3.89 × 10⁵ | |
| | 7 | 3.34 × 10⁹ | 1.24 × 10⁷ | 4.82 × 10⁶ | 8.21 × 10⁵ | 5.82 × 10⁵ | 6.52 × 10⁵ | |
| | 10 | 5.39 × 10¹⁰ | 6.39 × 10⁵ | 5.69 × 10⁶ | 7.42 × 10⁵ | 6.11 × 10⁵ | 6.51 × 10⁵ | |
| | 15 | 5.51 × 10¹¹ | 3.21 × 10¹¹ | 5.66 × 10⁷ | 9.24 × 10⁵ | 6.89 × 10⁵ | 6.89 × 10⁵ | |
| | 20 | 9.91 × 10¹² | 8.81 × 10¹² | 8.23 × 10⁹ | 4.29 × 10⁶ | 4.83 × 10⁶ | 1.32 × 10⁶ | |

In Table 1 above, when the concentration of pentaerythritol tris[3-(1-aziridinyl)propionate]was 0.6 wt %, gelation occurred on the surface and the appearance was poor.

As a test result, it was determined that the surface resistance was maintained low even after repeated rubbing of the solvent when the concentration of pentaerythritol tris[3-(1-aziridinyl)propionate]was 0.1 to 0.5 wt %, and thus the conductive layer had the solvent resistance.

### Examples 1 to 8 and Comparative Examples 1 and 2: Conductive Layer+Adhesive Layer

A product was obtained by reacting 27 g of polydimethylsiloxane (weight average molecular weight of 650,000) containing a vinyl group content of 0.2 mmol/g at both ends and 3 g of a methylhydrosiloxane-dimethylsiloxane copolymer (weight average molecular weight of about 2,500) having a Si—H content of 4 mmol/g at room temperature and pressure for 200 minutes using a 0.5 g/kg platinum aqueous solution in 9.5 g/kg of toluene as a catalyst. Then, the product was slot die-coated on the conductive layer of Preparation Example, and dried with 35 Hz hot air at 60° C. for 50 sec, 110° C. for 50 sec, and 150° C. for 50 sec to form an adhesive layer having a thickness of 20 μm (Example 1). The thickness of the conductive layer was changed to 0.02 μm (Comparative Example 1), 0.09 μm (Example 2), 0.15 μm (Example 3), 0.3 μm (Example 4), 0.9 μm (Example 5), 1.5 μm (Example 6), 2 μm (Example 7), 3 μm (Example 8), or 3.4 μm (Comparative Example 2), and an adhesive layer was formed.

### Test Example 2: Changes in Surface Resistance According to Thickness of Conductive Layer

The surface resistances of Examples 1 to 8 and Comparative Examples 1 and 2 were measured with a surface resistance meter (Mitsubishi Chemical, Japan) when a molar ratio of Si—H/vinyl group was 2 and an applied voltage was 1 kV. The results were shown in Table 2.

TABLE 2

| | Conductive layer | Surface resistance |
|---|---|---|
| | thickness (μm) | (Ω/sq) |
| Comparative Example 1 | 0.02 | 1.32 × 10¹³ |
| Example 1 | 0.03 | 7.54 × 10¹² |
| Example 2 | 0.09 | 4.13 × 10¹² |
| Example 3 | 0.15 | 1.39 × 10¹² |
| Example 4 | 0.3 | 9.81 × 10¹¹ |
| Example 5 | 0.9 | 8.84 × 10¹¹ |
| Example 6 | 1.5 | 5.93 × 10¹¹ |
| Example 7 | 2 | 4.39 × 10¹¹ |
| Example 8 | 3 | 3.82 × 10¹¹ |
| Comparative Example 2 | 3.4 | 2.83 × 10¹⁰ |

As a test result, when the thickness of the conductive layer was 0.03 to 0.3 μm, it was confirmed that the surface resistance value had a target range of 1×10¹¹ to 1×10¹³ Ω/sq.

### Test Example 3: Changes in Electrical Properties According to Molar Ratio of Si—H/Vinyl Group

When the Si—H molar ratio of methylsilane to vinyl groups contained in both ends of the polydimethylsiloxane of Example 1 was changed to 0.5 (Comparative Example 3), 1 (Example 9), 3 (Example 10), or 4 (Comparative Example 4), the surface resistance was measured using a surface resistance meter (Mitsubishi Chemical, Japan), and changes in dielectric loss and dielectric constant at 10 GHz were measured using a dielectric meter (Keysight, USA). After confirming whether it functioned as an electrostatic chuck, the results were shown in Table 3.

TABLE 3

| | Comparative | | | Comparative |
|---|---|---|---|---|
| | Example 3 | Example 9 | Example 10 | Example 4 |
| Si—H/vinyl | 0.5 | 1 | 3 | 4 |
| molar ratio | | | | |
| Surface | 1.13 × 10¹² | 4.43 × 10¹¹ | 5.21 × 10¹² | 7.23 × 10¹² |
| resistance | | | | |
| (Ω/sq) | | | | |
| Dielectric loss | 0.052 | 0.043 | 0.032 | 0.018 |
| Dielectric | 3.5 | 3.2 | 2.89 | 2.75 |
| constant | | | | |
| Electrostatic | Impossible | Possible | Possible | Impossible |
| chuck | | | | |

As a test result, it was confirmed that when the molar ratio of Si—H/vinyl group was 1 to 3, the dielectric loss and dielectric constant values had the target ranges of 0.02 to 0.1 and 2.8 to 3.3, respectively.

### Test Example 4: Changes in Electrical Properties According to Changes in Layer Order

The same process as Example 1 was followed, but the adhesive layer was formed under the base layer instead of on the conductive layer (Comparative Example 5), or one more conductive layer was formed under the base layer after preparing as in Example 1 (Comparative Example 6), and then changes in dielectric loss and dielectric constant at 10 GHz were measured using a dielectric measuring device (Keysight, USA) and it was confirmed whether it functioned as an electrostatic chuck, which was shown in Table 4. At this time, the molar ratio of Si—H/vinyl group was 2, and the thickness of the conductive layer was 0.3 μm.

TABLE 4

| | Comparative | Comparative | |
|---|---|---|---|
| | Example 5 | Example 6 | Example 11 |
| Layer order | Conductive/base/ | Conductive/base/ | Base/conductive/ |
| | adhesive | conductive/adhesive | adhesive |
| Dielectric | 0.127 | 0.133 | 0.084 |
| loss | | | |
| Dielectric | 3.31 | 3.33 | 3.15 |
| constant | | | |
| Electrostatic | Impossible | Impossible | Possible |
| chuck | | | |

As a test result, it was confirmed that the dielectric loss and dielectric constant values had the target ranges of 0.02 to 0.1 and 2.8 to 3.3, respectively, only when the base layer-conductive layer-adhesive layer were prepared in the order.

Although the preferred examples of the present disclosure have been described above, the present disclosure is not limited to the specific examples described above, and it is obvious that those skilled in the art may make various modifications without departing from the gist of the present disclosure. Therefore, the scope of the present disclosure should not be interpreted as limited to the examples, but should be determined by claims to be described below as well as equivalents of the claims.

### EXPLANATION OF REFERENCE NUMERALS AND SYMBOLS

| | |
|---|---|
| 10: Base layer | 20: Conductive layer |
| 30: Adhesive layer | 40: Release film. |

1. An electrostatic chuck film comprising:
a base layer;
a conductive layer formed on the base layer; and
an adhesive layer formed on the conductive layer.

2. The electrostatic chuck film of claim 1, further comprising:
a release film formed on the adhesive layer.

3. The electrostatic chuck film of claim 1, wherein when a voltage of 1 kV is applied to the electrostatic chuck film, a surface resistance is 1×10¹¹ to 1×10¹³ Ω/sq.

4. The electrostatic chuck film of claim 1, wherein when the voltage of 1 kV is applied to the electrostatic chuck film, a dielectric loss is 0.02 to 0.1.

5. The electrostatic chuck film of claim 1, wherein when the voltage of 1 kV is applied to the electrostatic chuck film, a dielectric constant is 2.8 to 3.3.

6. The electrostatic chuck film of claim 1, wherein the conductive layer is selected from the group consisting of poly(3,4-ethylenedioxythiophene (PEDOT), poly(3,4-ethylenedioxythiophene) polystyrenesulfonate (PEDOT-PSS), carbon nanotubes (CNT), graphene, indium tin oxide (ITO), silver nanowires, and combinations thereof.

7. The electrostatic chuck film of claim 1, wherein the adhesive layer is selected from the group consisting of silicone, acrylic resin, urethane resin, rubber, and combinations thereof.

8. The electrostatic chuck film of claim 1, wherein the thickness of the base layer is 25 to 100 μm, 33 to 70 μm, or 38 to 50 μm.
